(19) United States
(12) Patent Application Publication
(10) Pub. No.: US 2016/0233367 A1
(43) Pub. Date: Aug. 11, 2016

(54) ILLUMINATION SYSTEM AND MANUFACTURING METHOD THEREOF

(71) Applicant: FLEXWAVE CO., LTD., Zhubei City (TW)

(72) Inventors: Chun-Hsien CHOU, Taichung City (TW); Min-Hung HSU, Taipei City (TW); Cheng-Ming HUNG, New Taipei City (TW); Chia-Hsin CHOU, Taichung City (TW)

(21) Appl. No.: 14/680,781

(22) Filed: Apr. 7, 2015

(30) Foreign Application Priority Data
Feb. 6, 2015 (TW) 104103995

(51) Int. Cl. H01L 31/054; B29D 11/00; G02B 1/14; H02J 7/35; G02B 19/00; F21V 8/00

(52) U.S. Cl. CPC H01L 31/0547; G02B 19/0042; G02B 6/0003; G02B 1/14; H02J 7/35; B29D 11/00721

(57) ABSTRACT

An illumination system comprises a main waveguide, a scattering structure, and an extending waveguide. The main waveguide includes an incident face and a surface opposite the incident face, wherein external light passes through the incident face into the main waveguide. The scattering structure is disposed on or close to the surface of the main waveguide so as to scatter the external light transmitted into the main waveguide.

The extending waveguide has an illuminating surface and a joint interface between itself and the main waveguide. The joint interface is not shaded by the scattering structure and allows the scattered external light to pass through the illuminating surface to illuminate an illuminated area. According to an embodiment of the present invention, the illumination system is simple and efficiently collecting the external light in a broader incident angle to provide illumination. A method for manufacturing the illumination system is also disclosed.

### BACKGROUND OF THE INVENTION

1. Field of the Invention

The present invention relates to an illumination system and a manufacturing method thereof, particularly to an illumination system able to transmit solar light and a manufacturing method thereof.

2. Description of the Prior Art

The conventional solar tracking system collects and guides solar light for green energy illumination or solar power generation. Normally, it required a bulky support system and an optical mirror structure; hence the installation was usually limited by the space and location. The concentration ratio of the tracking system could be significantly influenced by the incident angle of solar light. Therefore, in order to capture solar light precisely, a direction control system is needed. However, such direction control system is expensive and inconvenient to operate. Besides, a direction control system may impair the light concentration effect of a solar tracking system.

Accordingly, how to capture solar light in a broad angle simply and efficiently has become a problem the researchers and manufacturers are eager to overcome.

### SUMMARY OF THE INVENTION

The present invention provides an illumination system and a manufacturing method thereof, which uses a soft waveguide material featuring flexibility, plasticity and wide-angle light capturing capability to conduct solar light for illumination. The soft waveguide material has superior weathering resistance and can be used to encapsulate and protect various electronic elements and modules. Therefore, the soft waveguide material can be used in various locations. Besides, the soft waveguide material is made of a high light transmission polymer or an organic polymer, which is environment-friendly, biocompatible and suitable for green energy application.

In one embodiment, the illumination system of the present invention comprises a main waveguide, a scattering structure and an extending waveguide. The main waveguide includes an incident face and a surface opposite the incident face, wherein external light passes the incident face into the main waveguide. The scattering structure is disposed on or close to the surface of the main waveguide so as to scatter the external light transmitted into the main waveguide. The extending waveguide has an illuminating surface and a joint interface between itself and the main waveguide. The joint interface is not shaded by the scattering structure and allows the scattered light to pass through the illuminating surface to illuminate an illuminated area.

In one embodiment, the method for manufacturing an illumination system of the present invention comprises steps: providing an extending waveguide having an illumination surface; placing a portion of the extending waveguide in a mold; filling a waveguide material in the mold and curing the waveguide material to form a main waveguide joined with the extending waveguide, wherein the main waveguide includes an incident face and a surface opposite the incident face and a scattering structure disposed on or close to the surface, and wherein the scattering structure does not shade a joint interface between the extending waveguide and the main waveguide.

Below, embodiments are described in detail in cooperation with the attached drawings to make easily understood the objectives, technical contents, characteristics and accomplishments of the present invention.

### BRIEF DESCRIPTION OF THE DRAWINGS

FIG. 1a is a diagram schematically showing an illumination system according to one embodiment of the present invention;

FIG. 1b is a diagram schematically showing an illumination system according to another embodiment of the present invention;

FIG. 2 is a diagram schematically showing an illumination system according to yet another embodiment of the present invention;

FIG. 3 is a diagram schematically showing an illumination system according to still another embodiment of the present invention;

FIG. 4 is a diagram showing a current-voltage relationship of an illumination system under an external light source according to one embodiment of the present invention; and

FIG. 5 is a diagram showing a current-voltage relationship of an illumination system under another external light source according to one embodiment of the present invention.

### DESCRIPTION OF THE PREFERRED EMBODIMENT

Below, embodiments of the present invention will be described in detail in cooperation with drawings. In addition to the embodiments described in the specification, the present invention also widely applies to other embodiments. Any substitute, modification or variation that can be easily completed according to the spirit of the present invention is to be included within the scope of the present invention, which is based on the claims of the present invention. Many special details are provided in the specification to enable the readers to comprehend the present invention. However, the present invention can still be practiced without a portion of or all the special details. Besides, the elements or steps, which are well known by the persons skilled in the art, are not described in the details lest they become unnecessary limitations on the present invention. Identical or similar elements will be denoted with identical or similar symbols in the drawings. It should be noted: the drawings do not present the actual sizes or numbers of the elements but only schematically show the present invention; some details may not be depicted in the drawings lest the conciseness of the drawings be impaired.

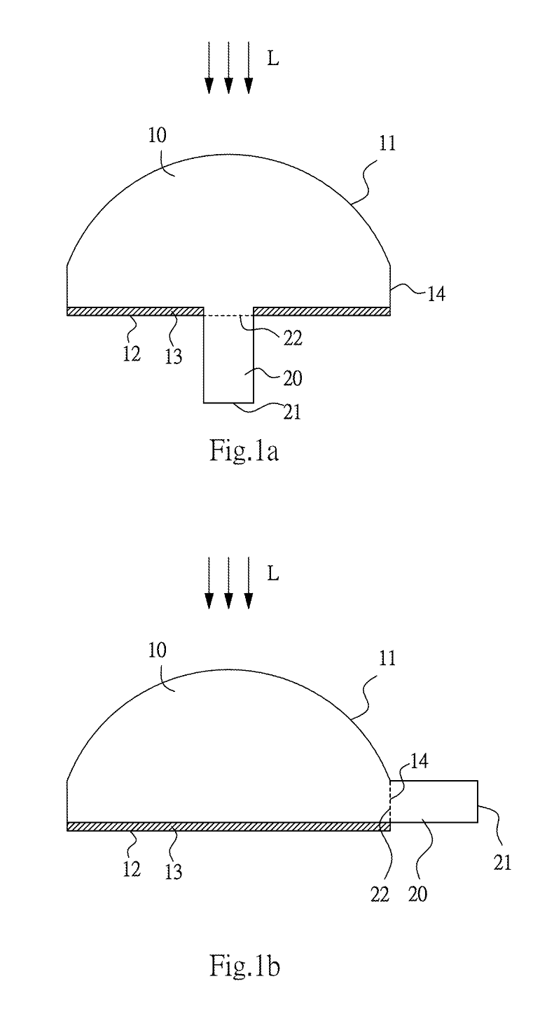

Refer to FIG. 1 a an illumination system according to one embodiment of the present invention. The illumination system of the present invention comprises a main waveguide 10, a scattering structure 13, and an extending waveguide 20. The main waveguide 10 includes an incident face 11 and a surface 12 opposite the incident face 11. In the embodiment shown in FIG. 1a, the incident face 11 is a protrudent semispherical surface. However, the present invention does not limit that the incident face 11 must be a protrudent semispherical surface. In one embodiment, the incident face 11 is extended to the surface 12 to form a semispherical main waveguide. In other embodiments, the incident face 11 is a plane or a concaved surface. The present invention does not particularly limit the shape of the main waveguide 10. The persons skilled in the art should be able to make appropriate modification or variation without departing from the spirit of the present invention. The scattering structure 13 is disposed on the surface 12 of the main waveguide 12 or embedded in the interior of the main waveguide 10, which are near the surface 12. For convenience, “disposed on the surface 12 or embedded in the interior of the main waveguide 10, which are near the surface 12” is stated as “disposed on or close to the surface 12 ” thereinafter. In other words, the scattering structure 13 is disposed on or close to the surface 12 of the main waveguide 10.

In the embodiment shown in FIG. 1a, the extending waveguide 20 has an illuminating surface 12 and is joined with the main waveguide 10. The extending waveguide 20 penetrates the scattering structure 13. Therefore, the scattering structure does not shade a joint interface 22 between the main waveguide 10 and the extending waveguide 20. Refer to FIG. 1b for another embodiment. In the embodiment shown in FIG. 1b, the extending waveguide 20 has an illuminating surface 21 and is joined with a side surface 14 of the main waveguide 10, wherein the side surface 14 is connected with at least one of the incident face 11 and the surface 12 of the main waveguide 10. In the embodiment shown in FIG. 1b, the scattering structure 13 does not shade the joint interface 22 between the main waveguide 10 and the extending waveguide 20.

While external light L passes the incident face 11 into the main waveguide 10, the external light L is scattered by the scattering structure 13. The scattered external light L enters the extending waveguide 20 and passes through the illuminating surface 21 to illuminate an illuminated area.

The main waveguide 10 is made of at least one of thermoplastic elastomer (TPE) and photocurable polymer (PCP). TPE is a high-resilience, environmental-protection, non-toxic and safe material. TPE is softer and more elastic than plastic material. The fabrication of TPE products is exempted from vulcanization. TPE has superior coloring capability and weathering resistance. The TPE waveguide materials include thermoplastic rubber (TPR), thermoplastic vulcanizate (TPV), thermoplastic polyurethane (TPP), and thermoplastic polyether ester elastomer (TPEE). The PCP waveguide material includes polydimethylsiloxane (PDMS). The usually used flexible waveguide materials are listed in Table.1.

TABLE 1

| Material (Abbreviation) | Classification |
|---|---|
| Polystyrene (PS) | TPR |
| Styrene-Ethylene/Butylene-Styrene | TPR |
| (SEBS) | |
| Polydimethylsiloxane (PDMS) | TPR/PCP |
| Polyvinyl Alcohol (PVA) | TPV |
| Polyvinyl Pyrrolidone (PVP) | TPV |
| Cycloolefin copolymer (COC) | TPV |
| Polyurethane (PU) | TPP |
| Polycarbonate (PC) | TPEE |
| Poly(Ethylene Terephthalate) (PET) | TPEE |
| Polyethylene Terephthalate (PETG) | TPEE |
| Poly methyl Methacrylate (PMMA) | TPEE/PCP |
| Styrene methyl Metacrylate (SMMA) | TPEE |

The present invention does not particularly limit the material of the extending waveguide 20. For example, the extending waveguide 20 may be fabricated with a usually used waveguide elements, such as optical fiber, glass tubes, or metallic tubes. Alternatively, the extending waveguide 20 is made of the same waveguide material as the main waveguide 10. Therefore, various electronic elements can be encapsulated inside the extending waveguide 20. In one embodiment, the scattering structure 13 includes a nanopowder or a white powder, which is doped on or closed to the surface 12 of the main waveguide 10 or coated on the surface 12 of the main waveguide 10. In other embodiments, the scattering structure 13 is a white reflective plate or a white coating layer. For example, the white coating layer is formed via smearing a white paint on the surface 12 of the main waveguide 10. In one embodiment, the scattering structure 13 includes a microstructure, which is disposed on the surface 12 of the main waveguide 10. For example, the microstructure is a conic microstructure, a semispherical microstructure, a rectangular microstructure, a roughened microstructure, or a combination thereof.

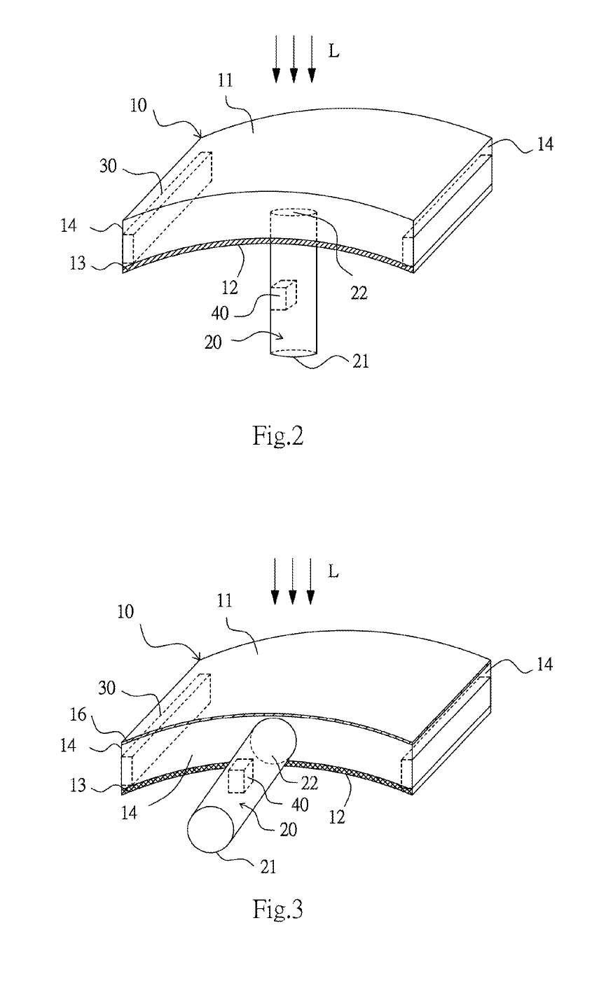

The flexible waveguide material used by the present invention has flexibility, plasticity and weathering resistance and is suitable to be fabricated into a one-piece component. The flexible waveguide material used by the present invention can be used to encapsulate and protect various electronic components and is suitable to be used in various locations. Refer to FIG. 2 for yet another embodiment of the present invention. In the embodiment shown in FIG. 2, the main waveguide 10 encapsulates at least one solar cell 30, which is disposed on or close to the side surface 14 of the main waveguide 10 or disposed on or close to the surface 12 of the main waveguide 10 and is not shaded by the scattering structure 13. However, the present invention does not limit that the solar cell 30 must be disposed on or close to the side surface 14 of the main waveguide 10 or disposed on or close to the surface 12 of the main waveguide 10. The extending waveguide 20 is also fabricated with the abovementioned soft waveguide material and encapsulates an electronic element 40, such as an illumination element. The electronic element 40 is disposed on at least one surface of the extending waveguide 20 or embedded inside the extending waveguide 20, electrically connected with the solar cell 30. In one embodiment, the main waveguide 10 is doped with a luminescent material or luminescent quantum dots, which absorb shorter-wavelength incident light (such as ultraviolet light) and convert the shorter-wavelength light into longer-wavelength light (such as infrared light), whereby to enhance the power generation efficiency of the solar cell.

It should be noted: the solar cell can be electrically connected with a rechargeable battery, which stores the power generated by the solar cell and provides power for an illumination element (such as a light emitting diode module) to illuminate indoors at night or on a cloudy day. In one embodiment, the extending waveguide 20 further encapsulates a sensing element, which detects the illuminance variation of the illuminated area and determines whether to turn on the illumination element. The abovementioned sensing element may be a RFID device, a detector or another electronic element. The persons with ordinary knowledge in the art should be able to modify or vary the embodiments without departing from the spirit of the present invention.

Refer to FIG. 3 for still another embodiment of the present invention. In the embodiment shown in FIG. 3, at least one surface of the main waveguide 10, e.g. at least one of the incident face 11 and the side surface 14 of the main waveguide 10, is overlaid with a protection layer 16 to enhance the stain resistance of the illumination system. The protection layer 16 is made of at least one transparent antifouling plastic material having a lower refractivity than the main waveguide 10, which is selected from a group consisting of ethylene-tetra-fluoro-ethylene (ETFE), ethylene-chlorotrifluororthylene (ECTFE), polytetrafluoroethylene (PTFE), fluorinated Ethylene Propylene (FEP), polyethylene terephthalate (PET), and polycarbonate (PC).

Below is described a method for manufacturing an illumination system according to one embodiment of the present invention. The waveguide material used by the present invention is at least one selected from a group consisting of polystyrene (PS), polycarbonate (PC), polyurethane (PU), cycloolefin copolymer (COC), poly(ethylene terephthalate) (PET), poly methyl methacrylate (PMMA), polyethylene terephthalate (PETG), styrene methyl metacrylate (SMMA), styrene-ethylene/butylene-styrene (SEBS), polyvinyl Alcohol (PVA), polyvinyl pyrrolidone (PVP), and polydimethylsiloxane (PDMS). In one embodiment, PDMS is used as the waveguide material because its plasticity, high transparency and high flexibility are favorable to manufacture an illumination system that guides solar light for illumination. A waveguide material is prepared beforehand: absorb an appropriate amount of PDMS;

add a curing agent to PDMS by a ratio (for example, the volume ratio of PDMS to the curing agent is 10:1); agitate the mixture uniformly; keep the mixture still for a period of time, or place the mixture in a vacuum chamber to remove bubbles, wherein the curing agent is not limited to a light curing agent or a thermal curing agent.

Firstly, provide an extending waveguide having an illuminating surface, wherein the present invention does not particularly limit the material of the extending waveguide. In one embodiment, the bubble-removed waveguide material is poured into an extending mold and heated at a temperature of 90-120° C. to cure the waveguide material and obtain an extending waveguide, wherein the extending waveguide uses the same material as the main waveguide. Next, place one end of the extending waveguide, which is opposite to the illuminating surface, in a mold. Next, fill a waveguide material into the mold and cure the waveguide material to form a main waveguide and join the extending waveguide with the main waveguide, wherein the main waveguide includes an incident face, a surface opposite the incident face and a scattering structure disposed on or close to the surface of the main waveguide, and wherein the scattering structure does not shade a joint interface between the extending waveguide and the main waveguide. Thereby is completed the illumination system shown in FIG. 1a or FIG. 1b.

In one embodiment, after a portion of the extending waveguide is placed in a mold, a solar cell is positioned inside the mold to dispose the solar cell on or close to the side surface of the main waveguide or dispose the solar cell on or close to the surface of the main waveguide, wherein the scattering structure does not shade the solar cell, and wherein the side surface is connected with al least one of the incident face and the surface of the main waveguide. Besides, while the bubble-removed waveguide material is poured into the extending mold, an electronic element is positioned inside the extending mold to dispose the electronic element on at least one surface of the extending waveguide or embed the electronic element inside the extending waveguide, wherein the electronic element is electrically connected with the solar cell. Thereby is completed an illumination system shown in FIG. 2 or FIG. 3. In one embodiment, a rechargeable battery is electrically connected with the solar cell.

In one embodiment, the waveguide material is blended with a nanopowder to form a nanopowder-containing mixture liquid. For example, mix TiO2 with PDMS uniformly by a ratio of TiO2: PDMS=0.5 g: 1 mL; next, mix the nanopowder-containing mixture liquid with a curing agent uniformly by a ratio of PDMS: curing agent=10:1; next, pour or smear the nanopowder and curing agent-containing mixture liquid on the bottom of the mold. After the waveguide material is cured, a scattering structure is formed on or close to the surface of the main waveguide. In other words, the scattering structuring is formed on an internal side near the surface of the main waveguide or smeared on the surface of the main waveguide. It is easily appreciated: the persons with ordinary knowledge of the art can replace the abovementioned nanopowder with a white powder to achieve the same scattering effect without departing from the spirit of the present invention. However, the present invention does not limit that the scattering structure must be fabricated with the abovementioned nanopowder or white powder. In one embodiment, one inner wall of the mold has a negative microstructure used to form a corresponding microstructure on the surface of the main waveguide, wherein the microstructure may be a conic microstructure, a semispherical microstructure, a rectangular microstructure, a roughened microstructure, or a combination thereof.

In one embodiment, one inner wall of the mold has a curved surface, a plane or a combination thereof to form a corresponding curve surface, a plane or a combination thereof on the main waveguide. In one embodiment, a protection layer is formed on at least one surface of the main waveguide to enhance the stain resistance of the illumination system, wherein the protection layer is made of at least one material selected from a group consisting of ethylene-tetra-fluoro-ethylene (ETFE), ethylene-chlorotrifluororthylene (ECTFE), polytetrafluoroethylene (PTFE), fluorinated Ethylene Propylene (FEP), polyethylene terephthalate (PET), and polycarbonate (PC).

Below are introduced tests for verifying the performance of an illumination system according to one embodiment of the present invention, wherein an illumination system whose main waveguide has an incident face with an area of 10×10 cm² is used as the sample. A 150 W halogen lamp with an illuminance of about 120 klx illuminates the illumination system from a position 20 cm away from the incident face of the main waveguide. The detected light transmission performance of the illumination system is listed in Table. 2.

TABLE 2

| | Light | |
|---|---|---|
| | Received | Light Output |
| Performance of | by Main | by Extending |
| Illumination System | Waveguide | Waveguide |
| Average Illuminance (klx) | 51 | 3.9 |
| Average Light Intensity | 600 | 200 |
| (W/m²) | | |

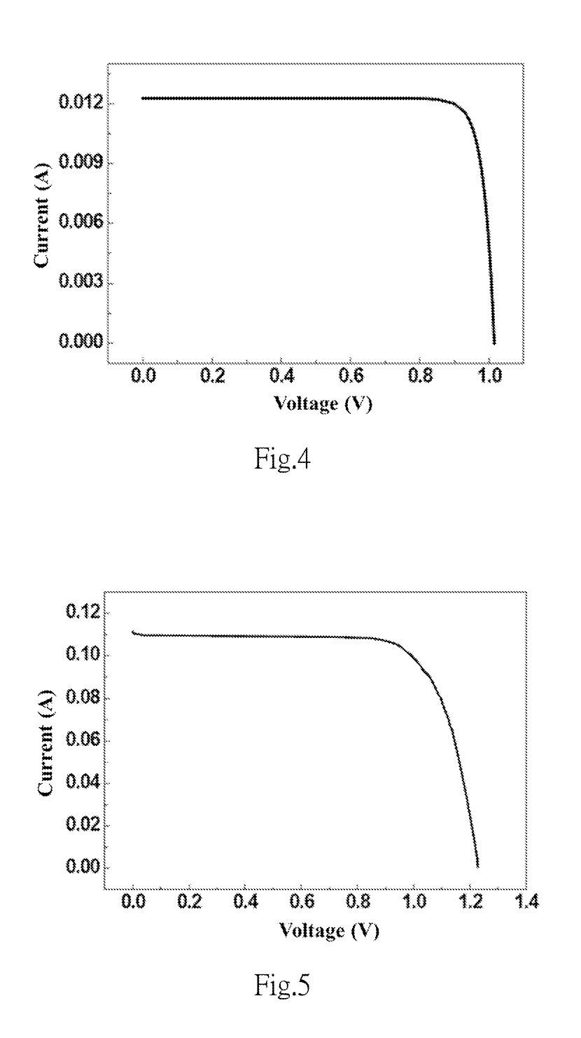

In the test, the current-voltage relationship of the solar cell is also detected and shown in FIG. 4. The open-circuit voltage of the solar cell is 1.008V; the short-circuit current of the solar cell is 0.012 A; and the filling factor (FF) is 0.89, which indicate that the illumination system of the present invention can use a portion of external light to generate electric power and has the efficacy of recycling light energy.

In the same embodiment, a 100 W LED lamp with an illuminance of about 450 klx is also used to illuminate the illumination system from a position 20 cm away from the incident face of the main waveguide, and the detected light transmission performance is listed in Table. 3.

TABLE 3

| | Light | |
|---|---|---|
| | Received | Light Output |
| Performance of | by Main | by Extending |
| Illumination System | Waveguide | Waveguide |
| Average Illuminance (klx) | 450 | 90 |
| Average Light Intensity | 1600 | 540 |
| (W/m²) | | |

In the test, the current-voltage relationship of the solar cell is also detected and shown in FIG. 5. The open-circuit voltage of the solar cell is 1.231V; the short-circuit current of the solar cell is 0.111 A; and the filling factor (FF) is 0.72, which indicate that the illumination system of the present invention can use a portion of external light to generate electric power and has the efficacy of recycling light energy.

From the above description, it should be easily appreciated: the illumination system of the present invention not only guides external (such as solar light) to illuminate an illuminated area but also uses a solar cell to recycle a portion of external light and generate electric power; the present invention adopts a waveguide material able to encapsulate various electronic elements; therefore, the present invention not only supplies power to the electronic elements but also provides weathering protection for the electronic elements.

In conclusion, the illumination system of the present invention and the manufacturing method thereof uses a soft waveguide material featuring flexibility, plasticity, and wide-angle light capture capability to guide external light for illumination. The soft waveguide material has superior weathering resistance and can encapsulate various electronic elements or modules. Therefore, the present invention is applicable to various locations. While the waveguide material also encapsulates at least one solar cell, the illumination system of the present invention further has a light energy recycling function. As the soft waveguide material used by the present invention is a high light transmission polymer or an organic polymer, the present invention is environment-friendly, biocompatible and suitable for green energy application.

What is claimed is:

1. An illumination system comprising
a main waveguide including an incident face and a surface opposite said incident face, wherein external light passes said incident face into said main waveguide;
a scattering structure disposed on or close to said surface of said main waveguide and scattering said external light transmitted into said main waveguide; and
an extending waveguide having an illuminating surface, wherein said scattering structure does not shade a joint interface between said extending waveguide and said main waveguide and allows said external light scattered by said scattering structure to pass through said illuminating surface to illuminate an illuminated area.

2. The illumination system according to claim 1, wherein said extending waveguide is joined with said surface or a side surface of said main waveguide, and wherein said side surface is joined with at least one of said incident face and said surface of said main waveguide.

3. The illumination system according to claim 2 further comprising
a solar cell disposed on or close to said side surface of said main waveguide or disposed on or close to said surface of said main waveguide, and not shaded by said scattering structure.

4. The illumination system according to claim 3 further comprising
a rechargeable battery electrically connected with said solar cell.

5. The illumination system according to claim 3 further comprising
an electronic element disposed on at least one surface of said extending waveguide or embedded inside said extending waveguide, and electrically connected with said solar cell.

6. The illumination system according to claim 1, wherein said main waveguide is doped with a luminescent material.

7. The illumination system according to claim 1, wherein said scattering structure includes a nanopowder or a white powder, which is doped on or close to said surface of said main waveguide or smeared on said surface of said main waveguide.

8. The illumination system according to claim 1, wherein said scattering structure includes a white reflective plate or a white coating layer.

9. The illumination system according to claim 1, wherein said scattering structure includes a microstructure disposed on said surface of said main waveguide.

10. The illumination system according to claim 9, wherein said microstructure includes a conic microstructure, a semispherical microstructure, a rectangular microstructure, a roughened microstructure, or a combination thereof.

11. The illumination system according to claim 1, wherein said incident face includes a curved surface, a plane, or a combination thereof.

12. The illumination system according to claim 1 further comprising
a protection layer disposed on at least one surface of said main waveguide and including at least one material selected from a group consisting of ethylene-tetra-fluoro-ethylene (ETFE), ethylene-chlorotrifluororthylene (ECTFE), polytetrafluoroethylene (PTFE), fluorinated Ethylene Propylene (FEP), polyethylene terephthalate (PET), and polycarbonate (PC).

13. The illumination system according to claim 1, wherein said main waveguide includes at least one material of thermoplastic elastomer (TPE) and photocurable polymer (PCP).

14. The illumination system according to claim 1, wherein said main waveguide includes at least one material selected from a group consisting of polystyrene (PS), polycarbonate (PC), polyurethane (PU), cycloolefin copolymer (COC), poly(ethylene terephthalate) (PET), poly methyl methacrylate (PMMA), polyethylene terephthalate (PETG), styrene methyl metacrylate (SMMA), styrene-ethylene/butylene-styrene (SEBS), polyvinyl Alcohol (PVA), polyvinyl pyrrolidone (PVP), and polydimethylsiloxane (PDMS).

15. The illumination system according to claim 1, wherein said main waveguide and said extending waveguide are made of an identical waveguide material.

16. A method for manufacturing an illumination system, comprising steps:
providing an extending waveguide having an illuminating surface;
placing a portion of said extending waveguide in a mold; and
filling a waveguide material in said mold, and curing said waveguide material to form a main waveguide and connect said extending waveguide with said main waveguide, wherein said main waveguide includes an incident face, a surface opposite said incident face, and a scattering structure disposed on or close to said surface, and wherein said scattering structure does not shade a joint interface between said extending waveguide and said main waveguide.

17. The method for manufacturing an illumination system according to claim 16, wherein said scattering structure is formed on or close to said surface of said main waveguide via blending said waveguide material with a nanopowder or a white powder before filling said waveguide material in said mold and curing said waveguide material, or formed via smearing said nanopowder or said white powder on said surface of said main waveguide, or formed via disposing a white reflective plate or a white coating layer on or close to said surface of said main waveguide.
